(19) United States
(12) Patent Application Publication
(10) Pub. No.: US 2011/0089446 A1
(43) Pub. Date: Apr. 21, 2011

(54) LIGHT-EMITTING DIODE HAVING OPTICAL FILM STRUCTURE THEREON

(76) Inventors: SHIH-LIANG KU, Xinpu Township (TW); Yung-Fang Chou, Pingxi Township (CN)

(21) Appl. No.: 12/581,142

(22) Filed: Oct. 18, 2009

(51) Int. Cl. H01L 33/00

(52) U.S. Cl. 257/98; 257/E33.067

(57) ABSTRACT

The invention discloses a light-emitting diode having an optical film structure thereon. The light-emitting diode includes a substrate, a light-emitting laminated structure, and an optical film structure. The light-emitting laminated structure is formed on the substrate, and the optical film structure is formed on the light-emitting laminated structure. The optical film structure is made of a dielectric material and has a light output plane, wherein the light output plane has plural roughened structures thereon.

### BACKGROUND OF THE INVENTION

1. Field of the Invention

The invention relates to a light-emitting diode, and particularly, the invention is to modify the reflection and the big-angle total internal reflection of the emergent light on the interface between the light-emitting diode and the air, so as to provide the light-emitting diode with better efficiency of light outputting.

2. Description of the Prior Art

The light-emitting diode (LED) generates light through the active region of the p-n interface thereof, and the lighting efficiency is decided by the internal quantum efficiency and the external quantum efficiency. The double heterojunction LED in fine processing conditions is provided with 95% internal quantum efficiency, but it only has 20% external quantum efficiency. When the light propagates out from the active region, three kinds of losses in the following cause bad light extraction efficiency and decrease the external quantum efficiency:
1. the absorption by the material;
2. the Fresnel Reflection Loss caused by the difference of the reflective index on the interface of the material: as shown in FIG. 1A, when the light propagates from a medium Ni to another medium Nt, a part of the light which is provided with an incident angle θi (θt is the refraction angle) less than the critical could not pass through the interface to bring about a loss. The loss is called Fresnel Reflection Loss and is decided by the reflective indexes of the two media, and if GaN is the material of the p-type layer (or n-type layer), 20% of the light could not pass through the interface to the air;
3. when the incident angle of the light propagating from the medium with high reflective index to the medium with low reflective index exceeds the critical angle θc, the total internal reflection occurs: the critical angle θc is decided by the reflective indexes of the two media and the formula is sin

$$θ c = \frac{{n}_{t}}{{n}_{i}} ,$$

wherein, nᵢ is the reflective index of the medium Ni and nₜ is the reflective index of the medium Nt. As shown in FIG. 1B, the light with the incident exceeding the critical angle θc could not pass through to the medium Nt. Similarly, taking GaN as the example for the material of the p-type layer (or n-type layer), the reflective index of GaN in visible light wave band is about 2.48 and the reflective index of the air is 1, so that the critical angle of this system is 23.6°. That is to say, the light with the incident angle exceeding 23.6° could not pass through to the air but reflected or absorbed by the inside, so the lighting efficiency of the device is not ideal.

For improving the light extraction efficiency, the usual way is roughening the surface of the p-type layer (or the n-type layer) to destroy the total internal reflection inside the LED. FIG. 2 is a cross-sectional view illustrating a used LED 1 in the prior art. The number 10 presents the substrate, the number 11 presents the n-type layer, the number 12 presents the active layer, and the number 13 presents the p-type layer. As shown in FIG. 2, the p-type layer 13 has roughened surface structures 130.

The total internal reflection could be destroyed by fabricating the roughened surface structures on surface of the p-type layer (or the n-type layer) through semiconductor technology, however, the semiconductor processes often need to etch the p-type layer (or the n-type layer) to cause the bad electric conductivity of the p-type layer (or the n-type layer) and the LED device. Besides, the roughening of the surface of the p-type layer (or the n-type layer) could not effectively modify the problem of the Fresnel Reflection Loss.

### SUMMARY OF THE INVENTION

The scope of the invention is to provide a light-emitting diode has the optical film structures on the surface thereof. The reflection and big-angle total internal reflection of the emergent light occurred on the interface between the light-emitting diode could be modified in the invention so as to increase the efficiency of light outputting effectively.

According to an embodiment of the invention, the light-emitting diode includes a substrate, a light-emitting laminated structure, and an optical film structure. The light-emitting laminated structure is formed on the substrate, and the optical film structure is formed on the light-emitting laminated structure.

It should be noted that the optical film structure is made of a dielectric material and has a light output plane, wherein the light output plane has a plurality of roughened structures. In an embodiment, the optical film structure is composed of a single optical film. In another embodiment, the optical film structure is composed of a plurality of optical films. In practice, the roughened structures could be formed on the light output plane periodically.

In efficacy, the optical film structure is provided with low-impedance matching for the light in a specific range of wavelength, and the specific range of wavelength is located in a wave band of ultraviolet or any one wave band of visible light.

In practice, the optical film material of the optical film structure is made of one selected from the group consisting of a metal oxide, a metal nitrogen oxide, and a metal fluoride, and the metal composition of the optical film material is one of the group consisting of titanium, tantalum, magnesium, silicon, indium, and tin.

It should be noted that, in an embodiment, the roughened structures formed on the light output plane includes a plurality of protruding structures, or in another embodiment, the roughened structures formed on the light output plane includes a plurality of hollow structures.

Because the light output plane forms a plurality of roughened structures, the roughened light output plane could decrease the reflection and the big-angle total internal reflection of the emergent light on the interface between the optical film structure and the air when the emergent light generated by the light-emitting diode propagates to the light output plane of the optical film structure. Therefore, the efficiency of light outputting of the light-emitting diode could be increased effectively.

To sum up, the influence of the Fresnel Reflection Loss and total internal reflection to the light-emitting diode of the invention could be modified by the optical film structure to increase the light extraction efficiency. Besides the influence of the total internal reflection, the periodic roughened structures could prevent deterioration of the electric conductivity caused by roughening the p-type semiconductor layer (or n-type semiconductor layer) of the light-emitting diode.

The advantage and spirit of the invention may be understood by the following recitations together with the appended drawings.

### BRIEF DESCRIPTION OF THE APPENDED DRAWINGS

FIG. 1A is a schematic diagram illustrating the refraction and the reflection of the light on the interface between different media in the prior art.

FIG. 1B is a schematic diagram illustrating the total internal reflection of the light in the medium.

FIG. 2 is a cross-sectional view illustrating a used LED in the prior art.

FIG. 3 is a cross-sectional view illustrating a light-emitting diode according to an embodiment of the invention.

FIG. 4 is a schematic diagram illustrating the relation of the light extraction efficiency and the incident angle of light of the light-emitting diode of the invention.

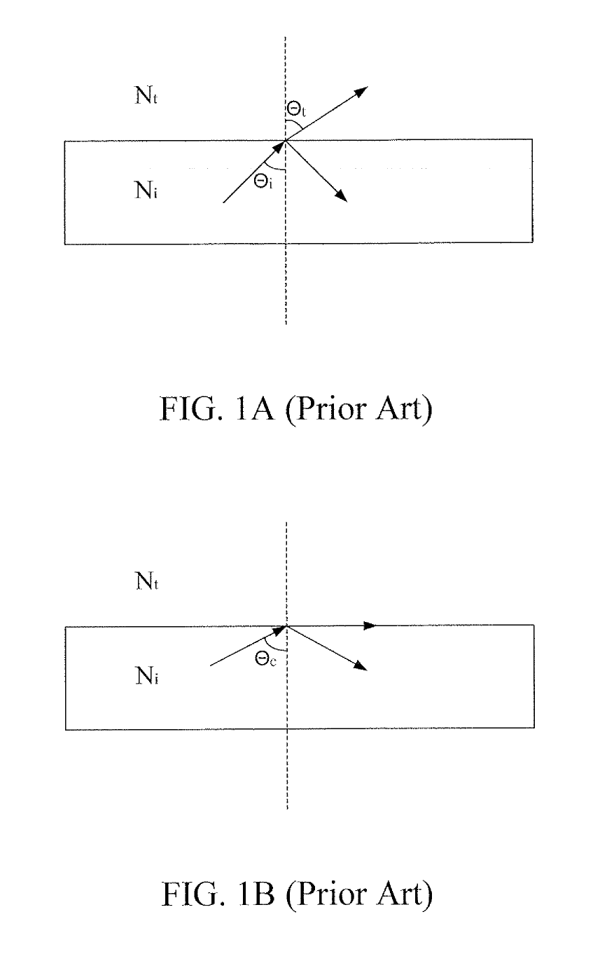

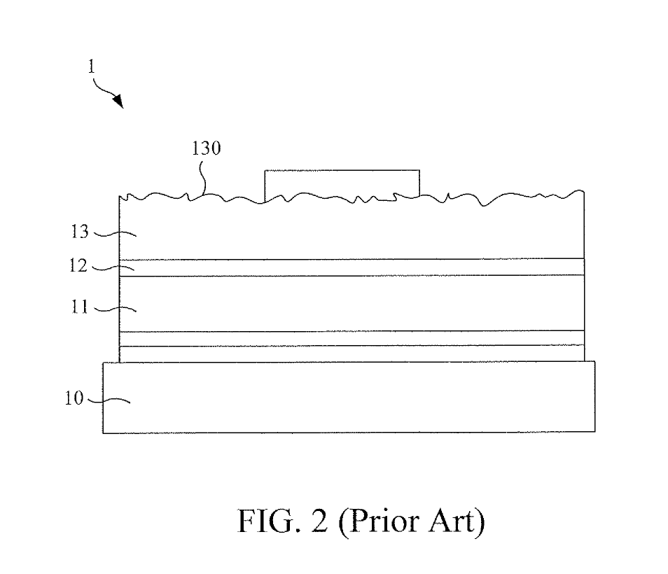

### DETAILED DESCRIPTION OF THE INVENTION

A scope of the invention is to provide a light-emitting diode having optical film structure on the surface thereof. The reflection and big-angle total internal reflection of the emergent light occurred on the interface between the light-emitting diode could be modified in the invention so as to increase the efficiency of light outputting effectively.

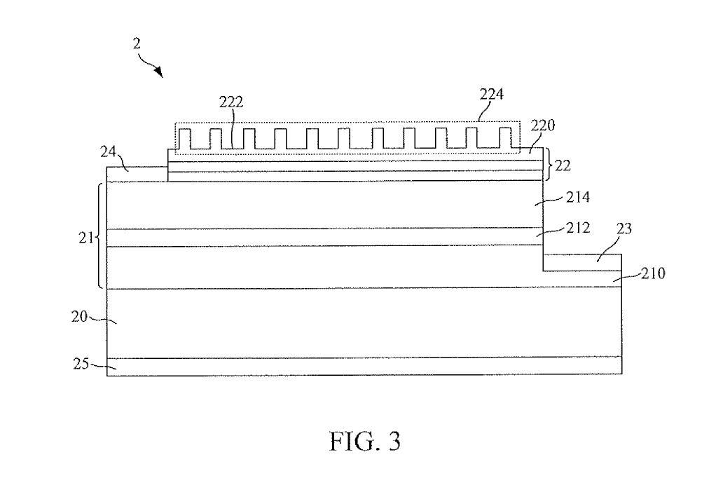

Please refer to FIG. 3. FIG. 3 is a cross-sectional view illustrating a light-emitting diode 2 according to an embodiment of the invention.

As shown in FIG. 3, the light-emitting diode 2 includes a substrate 20, a light-emitting laminated structure 21, an optical film structure 22, a first electrode 23, and a second electrode 24. The light-emitting laminated structure is formed on the substrate 20, and the optical film structure is formed on the light-emitting laminated structure 21. The light-emitting laminated structure 21 includes an active layer 212, an n-type semiconductor layer 210, and a p-type semiconductor layer 214, and the active layer 212 is between the n-type semiconductor layer 210 and the p-type semiconductor layer 214.

The substrate 20 is a plane-type substrate, and suitable semiconductor or metal-dielectric material could be chosen as the material of the substrate 20 according the wavelength of the outputting light. For example, if the wavelength of the outputting light is located in the band of visible light, sapphire could be chosen as the material of the substrate 20, but it is not a limitation.

Furthermore, the light-emitting diode 2 could include a reflective layer 25 formed on the lower surface of the substrate 20. The reflective layer 25 could be formed by PVD. The reflective layer 25 could be a single metal film layer such as silver (Ag), aluminum (Al), or copper (Cu), or could be a reflective film layer formed by stacking a plural of metal oxides, metal nitrides, and metal fluorides, wherein the metal composition is one of the group consisting of titanium (Ti), tantalum (Ta), magnesium (Mg), silicon (Si), and etc.

The light-emitting laminated structure 21 could be formed on the substrate 20 by epitaxy. The light-emitting laminated structure 21 could be provided with a single P-N structure or the lighting structure with multi quantum wells (MQW). The light-emitting diode in the embodiment could be made of GaN material, but it is not a limitation. Therefore, the n-type semiconductor layer 210 and the p-type semiconductor layer 214 could be GaN semiconductor layers. Besides, the first electrode 23 is an n-type electrode formed on the n-type semiconductor layer 210 and the second electrode 24 is a p-type electrode formed on the p-type semiconductor layer 214.

The optical film structure 22 could be formed on the upper surface of the light-emitting laminated structure 21 by PVD. It should be noted that the optical film structure is made of a dielectric material and has a light output plane 222, wherein the light output plane 222 forms a plurality of roughened structures 224.

In one embodiment, the optical film structure 22 could be composed of a single optical film 220, but in another embodiment, the optical film structure 22 could be composed of a plurality of optical film 220 stacking with each other. It should be noted that the plurality of optical film 220 could be made of the same material, or, they could be made of different materials with different reflective indexes. The range of the reflective index of the optical film 220 is between 1.39 and 2.55 in the wave band of visible light. In practice, the thickness of each optical film 220 is between several nanometers and several hundred nanometers.

In practice, the material of the optical film 220 of the optical film structure is made of one of the group consisting of a metal oxide, a metal nitrogen oxide, and a metal fluoride. The metal composition of the material of the optical film 220 is one of a group consisting of titanium, tantalum, magnesium, silicon, indium, and tin. The optical film 22 in this embodiment is made by three layer of TiO₂ and SiO₂ optical films with different thickness stacking with each other, wherein the thickness of single layer is between several dozens nanometers and one hundred nanometers. It should be noted that the kind of material, the film thickness, and the number of the film of the optical film structure 22 could be adjusted according to the wavelength of the outputting light.

As shown in FIG. 3, it should be noted that the roughened structures 224 formed on the light output plane 222 include a plurality of protruding structures. Or, in another embodiment, the roughened structures 224 formed on the light output plane 222 include a plurality of hollow structures. In practice, the roughened structure 224 could be formed on the light output plane 222 periodically. It should be noted that forming the roughened structures 224 periodically on the surface of the light film structure 22 could reach the purpose of destroying the total internal reflection of the emergent light.

The cross-section of the roughened structures 224 could be provided with, but not limited to, a geometry shape, such as a rectangle, a triangle, a cylinder, or a hemisphere. In this embodiment, the periodic roughened structure 224 is a cylinder construction made of SiO₂. The size and the period of the roughened structure 224 could be adjusted according to the wavelength of the emergent light. In efficacy, the optical film structure 22 is provided with low-impedance matching for the light in a specific range of wavelength, and the specific range of wavelength is located in a wave band of ultraviolet or any one wave band of visible light.

It should be noted that because the light output plane 222 forms a plurality of roughened structures 224 thereon, the roughened light output plane 222 could decrease the reflection and the big-angle total internal reflection of the emergent light on the interface between the optical film structure 22 and the air when the emergent light generated by the light-emitting diode propagates to the light output plane 222 of the optical film structure 22. Therefore, the efficiency of light outputting of the light-emitting diode could be increased effectively.

Besides, according to the material and thickness of the optical film and the shapes and sizes of the periodic roughened structures 224, the fabricating method of the periodic roughened structures 224 could be semiconductor etching process, nano-imprint, B-beam lithography, and etc.

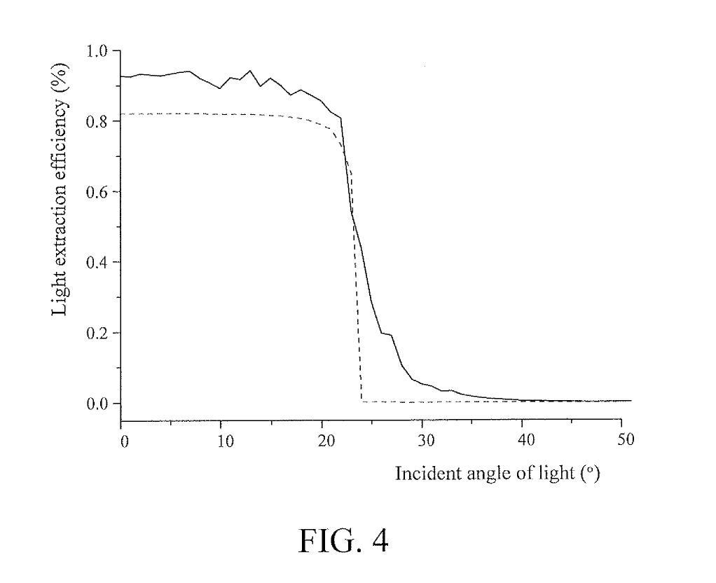

Please refer to FIG. 4. FIG. 4 is a schematic diagram illustrating the relation of the light extraction efficiency and the incident angle of light of the light-emitting diode of the invention. The relation is obtained by the far-field optical simulation according to the electromagnetic theory.

The dotted line in FIG. 4 presents the measuring curve of the light-emitting diode in the prior art, and the solid line presents the measuring curve of the light-emitting diode of the invention. As shown in FIG. 4, the periodic roughened structures of the light-emitting diode of the invention make the light to pass through from the p-type semiconductor layer to the air under the condition that the incident angle exceeds 23.6°, and it could increase 12% of the light outputting, so as to reach the purpose of increasing light extraction efficiency of the light-emitting diode device.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A light-emitting diode having optical film structure thereon, comprising:
a substrate;
a light-emitting laminated structure, formed on the substrate; and
an optical film structure, formed on the light-emitting laminated structure, the optical film structure being made of a dielectric material and having a light output plane, the light output plane having a plurality of roughened structures.

2. The light-emitting diode of claim 1, wherein the optical film structure is composed of a single optical film.

3. The light-emitting diode of claim 1, wherein the optical film structure is composed of a plurality of optical films.

4. The light-emitting diode of claim 2, wherein the optical film material of the optical film structure is made of one selected from the group consisting of a metal oxide, a metal nitrogen oxide, and a metal fluoride, and the metal composition of the optical film material is one of the group consisting of titanium, tantalum, magnesium, silicon, indium, and tin.

5. The light-emitting diode of claim 2, wherein the refractive index range of the visible light wave band of the optical film is between 1.39 and 2.55.

6. The light-emitting diode of claim 1, wherein the thickness of the optical film structure is between several nanometers to several hundred nanometers.

7. The light-emitting diode of claim 1, wherein the roughened structures formed on the light output plane comprises a plurality of protruding structures.

8. The light-emitting diode of claim 1, wherein the roughened structures formed on the light output plane comprises a plurality of hollow structures.

9. The light-emitting diode of claim 1, wherein the cross-section of the roughened structures formed on the light output plane has a geometry shape.

10. The light-emitting diode of claim 1, wherein the roughened structures are formed on the light output plane periodically.

11. The light-emitting diode of claim 1, wherein the light-emitting laminated structure comprises an active layer, an n-type semiconductor layer, and a p-type semiconductor layer, and the active layer is between the n-type semiconductor layer and the p-type semiconductor layer.

12. The light-emitting diode of claim 11, wherein the optical film structure is formed on the p-type semiconductor.

13. The light-emitting diode of claim 1, further comprising a reflective layer formed on the lower surface of the substrate.

14. The light-emitting diode of claim 1, wherein the optical film structure is provided with low-impedance matching for the light in a specific range of wavelength, and the specific range of wavelength is located in a wave band of ultraviolet or any one wave band of visible light.
